(19) United States
(12) Patent Application Publication
(10) Pub. No.: US 2020/0161361 A1
(43) Pub. Date: May 21, 2020

(54) IMAGE SENSOR AND FORMING METHOD THEREOF

(71) Applicant: HUAIAN IMAGING DEVICE MANUFACTURER CORPORATION, Huaian (CN)

(72) Inventors: Xinyi Huang, Huaian (CN); Chao ZHANG, Huaian (CN); Dailong Wei, Huaian (CN); Xiangpeng Zhang, Huaian (CN)

(21) Appl. No.: 16/688,199

(22) Filed: Nov. 19, 2019

(30) Foreign Application Priority Data
Nov. 21, 2018 (CN) 201811392984.7

(51) Int. Cl. H01L 27/146

(52) U.S. Cl. CPC H01L 27/14636; H01L 27/14643; H01L 27/14605; H01L 27/1463; H01L 27/1461; H01L 27/14692

(57) ABSTRACT

An image sensor and forming method thereof are disclosed. The image sensor comprises: a semiconductor substrate which comprises a first silicon substrate layer, a substrate oxide layer and a second silicon substrate layer that are stacked; a transmission gate electrode disposed on the surface of the second silicon substrate layer; a floating diffusion disposed in the semiconductor substrate on one side of the transmission gate electrode; a photodiode doped region disposed in the first silicon substrate layer; and a conductive via structure disposed in the semiconductor substrate on the other side of the transmission gate electrode, penetrating through the second silicon substrate layer and the substrate oxide layer and electrically connected to the photodiode doped region.

### CROSS REFERENCES TO RELATED APPLICATIONS

This application claims the benefit of priority to Chinese Patent Application No. CN201811392984.7, entitled “Image Sensor and Forming Method Thereof”, filed with CNIPA on Nov. 21, 2018, the contents of which are incorporated herein by reference in its entirety.

### TECHNICAL FIELD

The present disclosure relates to the technical field of semiconductor fabrication, and in particular, to an image sensor and its forming method.

### BACKGROUND

In order to achieve dielectric isolation of components in the integrated circuit and to eliminate the parasitic latch effect in the semiconductor device, silicon on insulator (SOI) substrate has been wildly used. The SOI substrate includes a first silicon substrate layer, a substrate oxide layer and a second silicon substrate layer that are stacked from the bottom up.

In the process of forming a CMOS image sensor (CIS) using SOI substrates, a photodiode (PD) doping region and a floating diffusion (FD) are generally only formed in the second silicon substrate.

However, the full well capacity (FWC) of a pixel unit decreases due to the space limitation for forming a PD region. Specifically, the full well capacity is the maximum charge that a pixel could maintain before saturation (which leads to signal degradation). When the charge in a pixel exceeds the saturation level, the charge begins to fill the adjacent pixels, which will result in the blooming, thereby degrading the quality of the image sensor.

Currently, the full well capacity of the pixel units could be increased through increasing the depth of the PD regions. However, the depth of the PD regions is limited by the thickness of the second silicon substrate layer in the SOI substrate, and the excessively deep depth of the PD regions will cause an image lag.

### SUMMARY

The present disclosure provides an image sensor, comprising: a semiconductor substrate which comprises a first silicon substrate layer, a substrate oxide layer and a second silicon substrate layer that are stacked; a transmission gate electrode disposed on a surface of the second silicon substrate layer; a floating diffusion disposed in the semiconductor substrate on one side of the transmission gate electrode; a photodiode doped region disposed in the first silicon substrate layer; and a conductive via structure disposed in the semiconductor substrate on the other side of the transmission gate electrode, penetrating through the second silicon substrate layer and the substrate oxide layer and electrically connected to the photodiode doped region.

Optionally, the boundary of the photodiode doped region extends to below the floating diffusion.

Optionally, the material of the conductive via structure is N-type doped poly-silicon.

Optionally, the image sensor also comprises: an N-type doped silicon region disposed in the first silicon substrate layer, through which the conductive via structure is electrically connected with the photodiode doped region; the doping concentration in the N-type doped silicon region is higher than that in the photodiode doped region.

The present disclosure further provides a method of forming an image sensor, comprising: providing a semiconductor substrate which comprises a first silicon substrate layer, a substrate oxide layer and a second silicon substrate layer that are stacked; forming a conductive trench which penetrates through the second silicon substrate layer and the substrate oxide layer; filling the conductive trench with a conductive material to form a conductive via structure; forming a floating diffusion in the semiconductor substrate; forming a transmission gate electrode on a surface of the second silicon substrate layer; forming a photodiode doped region in the first silicon substrate layer, and the photodiode doped region is electrically connected with the conductive via structure; the floating diffusion is disposed in the semiconductor substrate on one side of the transmission gate electrode, and the conductive via structure is disposed in the semiconductor substrate on the other side of the transmission gate electrode.

Optionally, the first silicon substrate layer has a front and a back, the front of the first silicon substrate layer is in contact with the substrate oxide layer, forming the photodiode doped region in the first silicon substrate layer, the method further comprises steps of: thinning the first silicon substrate layer from the back; and implanting ions into the first silicon substrate layer from its back to form the photodiode doped region.

Optionally, the boundary of the photodiode doped region extends to below the floating diffusion.

Optionally, the material of the conductive via structure is N-type doped poly-silicon.

Optionally, before the step of forming the conductive via structure through filling the conductive trench with a conductive material, the method of forming an image sensor further comprises: implanting ions into the first silicon substrate layer exposed from the bottom of the conductive trench to form an N-type doped silicon region disposed in the first silicon substrate layer; the bottom of the N-type doped silicon region is connected with the photodiode doped region, and the doping concentration in the N-type doped silicon region is higher than that in the photodiode doped region.

Optionally, the doping concentration in the N-type doped silicon region is lower than that in the floating diffusion.

Compared to image sensor in prior art, the present disclosure has the following beneficial effects:

Compared with setting the photodiode doped region in the second silicon substrate layer, the present disclosure can transfer the photodiode doped region to the first silicon substrate layer (which has more space), without affecting the photo-generated carriers to move from the photodiode doped region to the floating diffusion, thus obtaining a higher full well capacity.

Further, the boundary of the photodiode doped region extends to below the floating diffusion. Compared with the photodiode doped region in the semiconductor substrate on one side of the transmission gate electrode, where the width and depth of the photodiode doped region are both limited, in the present disclosure, the photodiode doped region has larger area, helping to enhance the quality of the image sensor.

Further, the material of the conductive via structure is N-type doped poly-silicon. When the transmission gate electrode is opened, photo-generated carriers can move to the floating diffusion from the photodiode doped region through the conductive via structure under the influence of potential energy.

Further, the image sensor also comprises an N-type doped silicon region, and the doping concentration in the N-type doped silicon region is higher than that in the photodiode doped region. In the present disclosure, a step change in the concentration from the photodiode doped region to the N-type doped silicon region is formed, which helps make more photo-generated carriers move between the photodiode doped region and the N-type doped silicon region, thus improving the quality of the image sensor.

### BRIEF DESCRIPTION OF THE DRAWINGS

FIG. 1 is a cross-sectional diagram of an image sensor in prior art.

FIG. 2 is a flow chart illustrating the forming method of an image sensor according to an embodiment of the present disclosure.

FIGS. 3-9 are the cross-sectional diagrams of the devices after each step of the forming method according to an embodiment of the present disclosure.

### DETAILED DESCRIPTION OF THE PREFERRED EMBODIMENTS

The foregoing objectives, features and advantages of the present disclosure will become more apparent from the following detailed description of specific embodiments of the disclosure in conjunction with the accompanying drawings. In the detailed description of the embodiments of the present disclosure, for convenience of description, the schematic diagram will be partially enlarged not according to an ordinary ratio, and the schematic diagram is only an example, which should not limit the protection scope of the present disclosure. In addition, three-dimensional space dimensions of length, width and depth should be comprised in actual production.

The implementation manners of the present disclosure will be described below with reference to specific examples. Those skilled in the art may easily understand other advantages and effects of the present disclosure by the contents disclosed in the present specification. The present disclosure may also be implemented or applied through other different specific implementation manners. Various modifications or changes may also be made on the details in the present specification without departing from the spirit of the present disclosure based on different viewpoints and applications.

It should be noted that the illustration provided in the present embodiment merely illustrates the basic concept of the present disclosure by way of illustration. Although only components related to the present disclosure are shown in the illustration, they are not drawn according to the number, shape and size of the components in actual implementation. The form, quantity and proportion of various components in actual implementation may be a random change, and the layout of the components may also be more complex.

In the current image sensor, in order to increase the full well capacity of the pixel units, the PD region needs to be increased.

As a result of research, the inventors of the present disclosure found that, it is difficult to increase the full well capacity of the pixel units by directly increasing the depth or width of the PD region.

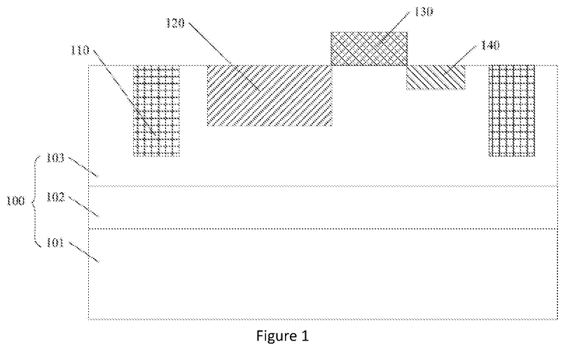

Referring to FIG. 1, FIG. 1 is a cross-sectional diagram of a current image sensor.

The image sensor may include a semiconductor substrate 100, the semiconductor substrate 100 may include a first silicon substrate layer 101, a substrate oxide layer 102, and a second silicon substrate layer 103 that are stacked.

The image sensor may include a photodiode doped region 120, a transmission gate electrode 130 and a floating diffusion 140.

The transmission gate electrode may be disposed on the second silicon substrate layer 103, the photodiode doped region 120 may be disposed in the second silicon substrate layer 103 on one side of the transmission gate electrode 130. The floating diffusion 140 may be disposed in the second silicon substrate layer 103 on the other side of the transmission gate electrode.

Further, the image sensor may include an isolation structure 110. The isolation structure 110 isolates the semiconductor devices in the second silicon substrate layer 103.

As is shown in FIG. 1, since the depth of the photodiode doped region 120 is constrained by the thickness of the second silicon substrate layer in the semiconductor substrate, when increasing the full well capacity of the pixel units through increasing the depth of the photodiode doped region 120, the increased space is very limited. In addition, simply increasing the depth of the photodiode doped region 120 may lead to image lag.

In another image sensor in prior art, the photodiode doped region is L-shape, so that the boundary of the photodiode doped region extends in the second silicon substrate layer to below the floating diffusion, thereby increasing the photodiode doped region. However, as the distance between the photodiode doped region and the floating diffusion is small, electronic crosstalk easily occurs.

The present disclosure provides an image sensor. The image sensor includes a semiconductor substrate, a transmission gate electrode, a floating diffusion, a photodiode doped region, and a conductive via structure. The semiconductor substrate includes a first silicon substrate layer, a substrate oxide layer and a second silicon substrate layer that are stacked. The transmission gate electrode is disposed on the second silicon substrate layer. The floating diffusion is disposed in the semiconductor substrate on one side of the transmission gate electrode. The photodiode doped region is disposed in the first silicon substrate layer. The conductive via structure is disposed in the semiconductor substrate on the other side of the transmission gate electrode, penetrates through the second silicon substrate layer and the substrate oxide layer, and is electrically connected to the photodiode doped region. By adopting the above solution, the photodiode doped region is disposed in the first silicon substrate layer in the semiconductor substrate, and the conductive via structure is disposed in the semiconductor substrate on the other side of the transmission gate electrode and is electrically connected to the photodiode doped region. Compared with image sensor in prior art, the present disclosure transfers the photodiode doped region to the first silicon substrate layer which has more space, without affecting the photo-generated carriers to move from the photodiode doped region to the floating diffusion.

To make it clear and easy to understand the above-mentioned objectives, features and advantages of the present disclosure, a detailed description of embodiments of the present disclosure combined with the attached drawings is given as follows.

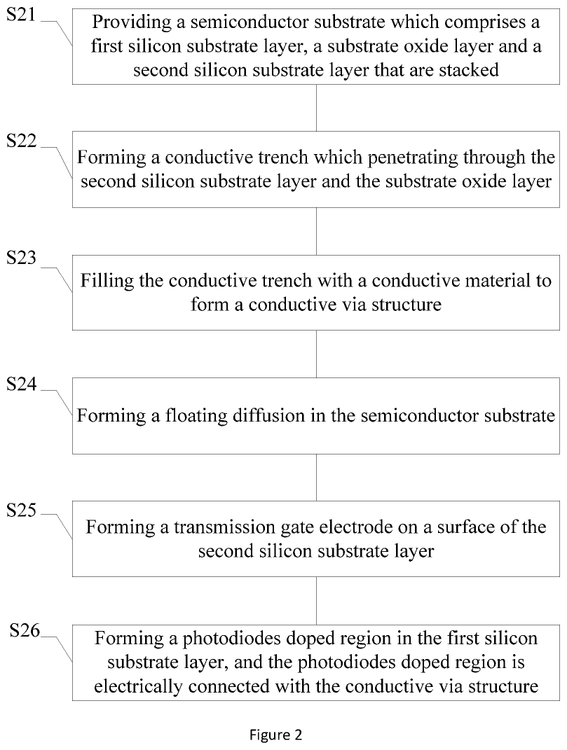

Referring to FIG. 2, FIG. 2 is the flow chart illustrating the forming method of an image sensor in an embodiment of the present disclosure. The forming method of the image sensor includes step S21 to S26:

Step S21: providing a semiconductor substrate which includes a first silicon substrate layer, a substrate oxide layer and a second silicon substrate layer that are stacked;

Step S22: Forming a conductive trench which penetrates through the second silicon substrate layer and the substrate oxide layer;

Step S23: Filling up the conductive trench with a conductive material to form a conductive via structure;

Step S24: Forming a floating diffusion in the semiconductor substrate;

Step S25: Forming a transmission gate electrode on the second silicon substrate layer;

Step S26: Forming a photodiode doped region in the first silicon substrate layer, and the photodiode doped region is electrically connected with the conductive via structure;

The floating diffusion is disposed in the semiconductor substrate on one side of the transmission gate electrode, and the conductive via structure is disposed in the semiconductor substrate on the other side of the transmission gate electrode.

Steps mentioned above are described below in connection with FIGS. 3 to 9.

FIGS. 3-9 are the cross-sectional diagrams of the devices after each step of the forming method of an image sensor according to an embodiment of the present disclosure.

Referring to FIG. 3, a semiconductor substrate 200 is provided. The semiconductor substrate 200 includes a first silicon substrate layer 201, a substrate oxide layer 202 and a second silicon substrate layer 203 that are stacked. A first isolation structure 210 is formed in the semiconductor substrate 200.

The semiconductor substrate 200 may be SOI substrate, or other semiconductor substrates that have stack structure. The material of the substrate oxide layer 202 may be monox, such as SiO2.

Note that the first silicon substrate layer 201 and the second silicon substrate layer 203 may be the most widely used silicon substrate, or silicon substrate or germanium substrate on the surface of insulators. In addition, the first silicon substrate layer 201 and the second silicon substrate layer 203 may be made of materials suitable for image sensor such as germanium, silicon germanide, silicon carbide, gallium arsenide or indium gallium, etc. Optionally, the second silicon substrate layer 203 may be a substrate that has an epitaxy layer (Epi layer).

Further, a first isolation structure 210 may be formed in the semiconductor substrate 200. The first isolation structure 210 is used to isolate the multiple active regions. Each active region includes the photodiode doped region and the floating diffusion that are respectively disposed on opposite sides of the same transmission gate electrode. In an embodiment of the present disclosure, since the photodiode doped region is disposed in the first silicon substrate layer 201, each active region may further include the conductive via structure and floating diffusion that are respectively located on the opposite sides of the same transmission gate electrode

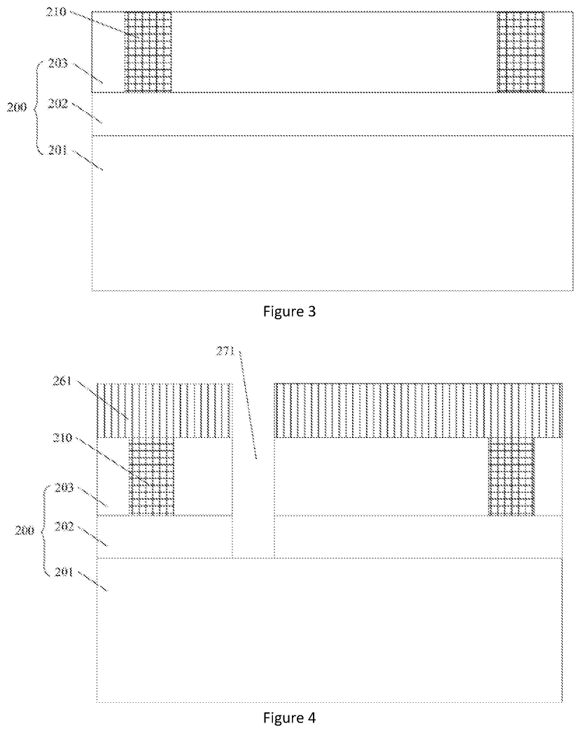

Referring to FIG. 4, a patterned mask layer 261 is formed on the second silicon substrate layer 203. The patterned mask layer 261 is used as the mask to etch the second silicon substrate layer 203 and the substrate oxide layer 202, so as to form the conductive trench 271.

Specifically, the conductive trench 271 penetrates through the second silicon substrate layer 203 and the substrate oxide layer 202.

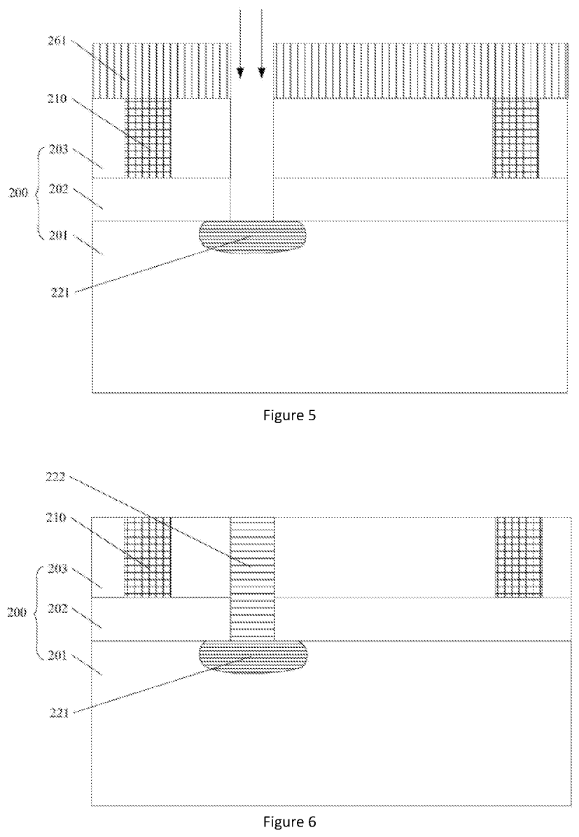

Referring to FIG. 5, implanting ions into the first silicon substrate layer 201 exposed at the bottom of the conductive trench 271 (referring to FIG. 4), so as to form an N-type doped silicon region 221 in the first silicon substrate layer 201.

The doping ions of the N-type doped silicon region 221 may be N-type, such as P, As or Sb.

As a non-limiting example, P ions may be used as the implanted ions, with implanting energy of 3 KeV to 7 KeV and implanting concentration of 1E13 to 1E14.

In an embodiment of the present disclosure, the mask layer 261 can be reused in the ion implanting process to protect the first silicon substrate layer 201.

In particular embodiments, the bottom of the N-type doped silicon region 221 may be connected with the subsequently-formed photodiode region, and the doping concentration in the N-type doped silicon region 221 is higher than that in the photodiode doped region.

In an embodiment of the present disclosure, the image sensor may further include an N-type doped silicon region 221. The doping concentration in the N-type doped silicon region 221 is higher than that in the subsequently-formed photodiode doped region. In the solution according to the present disclosure, a step change in the concentration from the photodiode doped region to the N-type doped silicon region 221 is formed, which helps make more photo-generated carriers move between the photodiode doped region and the N-type doped silicon region 221, improving the quality of the image sensor.

Referring to FIG. 6, the conductive trench is filled up with a conductive material to form the conductive via structure 222.

In particular embodiments, the conductive via structure 222 is used to transfer the photo-generated carriers (such as electrons) from the photodiode doped region to the floating diffusion.

Further, the material of the conductive via structure 222 may be N-type doped poly-silicon.

Note that the material of the conductive via structure may be other conductive materials, such as germanium-silicon (GeSi) material.

Specifically, metal materials or metal silicide materials may cause metallic contamination, and is difficult to transfer enough photo-generated carriers when the transmission gate electrode opens. According to the present disclosure, the conductive via structure 222 is formed by N-type doped poly-silicon, metallic contamination can be avoided, and the photo-generated carriers can be better transferred from the photodiode doped region to the floating diffusion under the influence of the potential energy when the transmission gate electrode opens.

In a particular embodiment, silicon source gas and dopant source gas may be provided into the reaction chamber to form N-type doped poly-silicon in the conductive trench through a deposition process, that is, to form the conductive via structure 222. The dopant source gas is used to provide the N-type doping ions.

In an embodiment of the present disclosure, the conductive via structure 222 may be N-type doped poly-silicon. When the transmission gate electrode opens, the photo-generated carriers move from the photodiode doped region to the floating diffusion through the conductive via structure 222 under the influence of potential energy.

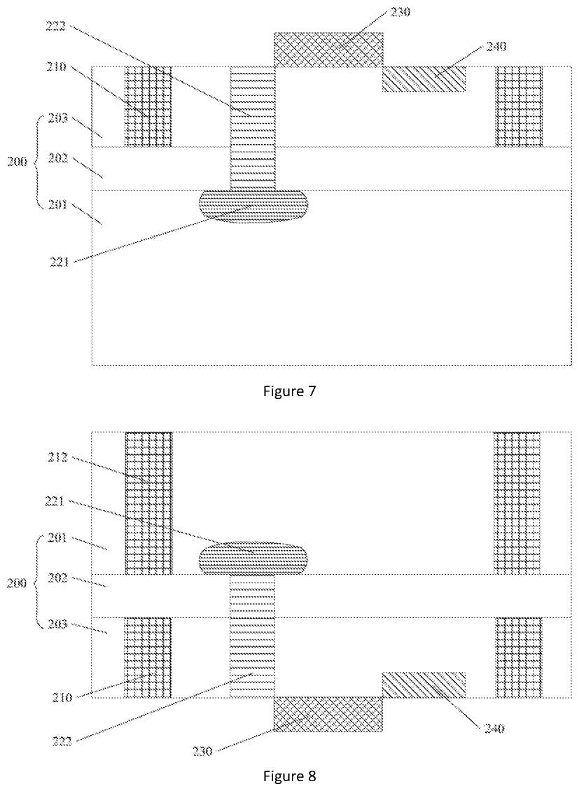

Referring to FIG. 7, the floating diffusion 240 is formed in the semiconductor substrate 200, and the transmission gate electrode 230 is formed on the second silicon substrate layer 203.

Specifically, the floating diffusion 240 may be formed by an ion implantation process. The floating diffusion 240 may be disposed in the semiconductor substrate 200 on one side of the transmission gate electrode 230, the conductive via structure 222 may be disposed in the semiconductor substrate 200 on the other side of the transmission gate electrode 230.

Note that a transfer channel is provided in the semiconductor substrate below the transmission gate electrode 230. By applying a voltage on the transmission gate electrode 230, the conductive via structure 222 and the floating diffusion 240 may be conducted or interrupted, so as to realize the transmission of the photo-generated carriers. It can be understood that the floating diffusion 240 may be disposed in the second silicon substrate layer 202, so as to better receive the photo-generated carriers. However, the embodiments of the present disclosure do not limit the specific location of the floating diffusion 240.

Further, the doping concentration in the N-type silicon doped region 221 may be less than that in the floating diffusion 240.

The doping ions of the floating diffusion can be N-type, such as P, As or Sb.

As a non-limiting example, P ions may be used as the implanted ions, with implanting energy of 5 KeV to 10 KeV and implanting concentration of 1E15 to 1E16.

In an embodiment of the present disclosure, the doping concentration in the N-type doped silicon region 221 is less than that in the floating diffusion 240, a step change of successively increasing doping concentration from the photodiode doped region to the N-type doped silicon region 221 and the floating diffusion 240 is formed, which helps more photo-generated carriers move between the photodiode doped region and the N-type doped silicon region 221 and the floating diffusion 240, thus improving the quality of the image sensor.

Referring to FIG. 8, thinning the first silicon substrate layer 201 from the back, and thus a second isolation structure 212 can be formed in the semiconductor substrate 200.

The first silicon substrate layer 201 has a front and a back, the front of the first silicon substrate layer 201 is in contact with the substrate oxide layer 202.

Specifically, when the material of the substrate oxide layer 202 is silicon oxide which has isolation function, the second isolation structure 212 may be disposed in the first silicon substrate layer 201 to isolate the subsequently formed photodiode doped region.

Note that the widths of the second isolation structure 212 and the first isolation structure 210 can be the same or different. In an embodiment of the present disclosure, the widths of the second isolation structure 212 and the first isolation structure 210 are not restricted.

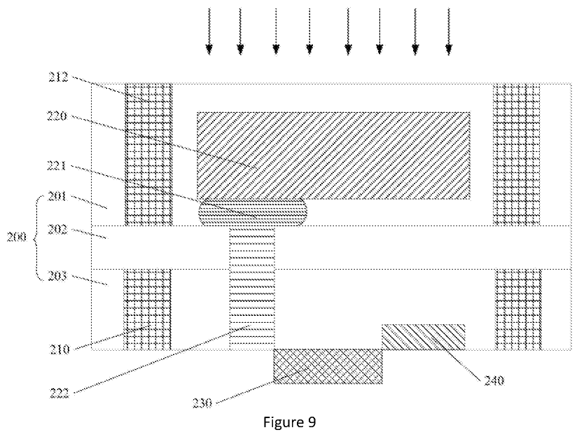

Referring to FIG. 9, ions are implanted into the first silicon substrate layer 201 from the back of the first silicon substrate layer 201 to form the photodiode doped region 220. The photodiode doped region 220 is electrically connected with the conductive via structure 222.

The bottom of the N-type doped silicon region 201 is connected with the photodiode doped region 220, and the doping concentration in the N-type doped silicon region 201 is larger than that in the photodiode doped region 220.

In an embodiment of the present disclosure, the photodiode doped region 220 is disposed in the first silicon substrate layer 201 in the semiconductor substrate 200, and the conductive via structure 222 is disposed in the semiconductor substrate 200 on the other side of the transmission gate electrode 230 and is electrically connected to the photodiode doped region 220. Compared with image sensor in prior art, the present disclosure can transfer the photodiode doped region 220 to the first silicon substrate layer (which has more space), without affecting the photo-generated carriers to move from the photodiode doped region 220 to the floating diffusion 240, thus obtaining a higher full well capacity.

Further, the boundary of the photodiode doped region 220 may extend to below the floating diffusion 240.

In an embodiment of the present disclosure, the boundary of the photodiode doped region 220 extends to below the floating diffusion 240. In the image sensor of prior art, the photodiode doped region 220 is disposed in the semiconductor substrate 200 on one side of the transmission gate electrode 230, and the width and depth of the photodiode doped region 220 are both limited. In the present disclosure, the photodiode doped region 220 has larger area, which helps enhance the quality of the image sensor.

Note that in an embodiment of the present disclosure, the photodiode doped region 220 may be deeper, such as 2-5 um, preferably 4 um.

Take the depth of the photodiode doped region 220 being 4 um for example, as a non-restrictive example, the implanting energy of the ion implanting process may be greater than or equal to 8 MeV, and the implanting concentration may be 1E12 to 1E13.

Further, in order to enhance the homogeneity of the concentration of the photodiode doped region 220, the ions may be implanted for multiple times with different energy, and then annealing process is adopted to make the photodiode doped region 220 more uniform.

In an embodiment of the present disclosure, an image sensor is provided. Referring to FIG. 9, the image sensor includes: a semiconductor substrate 200 including a first silicon substrate layer 201, a substrate oxide layer 202 and a second silicon substrate layer 203 that are stacked; a transmission gate electrode 230 disposed on the second silicon substrate layer 202; a floating diffusion 240 disposed in the semiconductor substrate 200 on one side of the transmission gate electrode 230; a photodiode doped region 220 disposed in the first silicon substrate layer 201; and a conductive via structure 222 disposed in the semiconductor substrate 200 on the other side of the transmission gate electrode 230, penetrating through the second silicon substrate layer 203 and the substrate oxide layer 202 and electrically connected to the photodiode doped region 220.

Further, the boundary of the photodiode doped region 220 may extend to below the floating diffusion 240.

Further, the material of the conductive via structure 222 may be N-type doped poly-silicon.

Further, the image sensor further includes an N-type doped silicon region 221 disposed in the first silicon substrate layer 201, through which the conductive via structure 222 is electrically connected with the photodiode doped region 220. The doping concentration in the N-type doped silicon region 221 is higher than that in the photodiode doped region 220.

Further, the doping concentration in the N-type doped silicon region 221 could be lower than that in the floating diffusion 240.

For the principle, embodiments and the beneficial effects of the image sensor, please refer to the relevant description of the formation method of the image sensor shown above and in FIGS. 2-9, thus it is not repeated here for brevity.

Although the disclosure is disclosed as above, the present disclosure is not limited thereto. Those skilled in the art may make various changes and modifications without deviating from the spirit and scope of the disclosure, so the scope of protection of the disclosure shall be subject to the scope defined by the claim.

1. An image sensor, comprising:
a semiconductor substrate, comprising a first silicon substrate layer, a substrate oxide layer and a second silicon substrate layer that are stacked;
a transmission gate electrode, disposed on a surface of the second silicon substrate layer;
a floating diffusion, disposed in the semiconductor substrate on one side of the transmission gate electrode;
a photodiode doped region, disposed in the first silicon substrate layer; and
a conductive via structure, disposed in the semiconductor substrate on the other side of the transmission gate electrode, penetrating through the second silicon substrate layer and the substrate oxide layer, and electrically connected to the photodiode doped region.

2. The image sensor according to claim 1, wherein the boundary of the photodiode doped region extends to below the floating diffusion.

3. The image sensor according to claim 1, wherein the material of the conductive via structure is N-type doped poly-silicon.

4. The image sensor according to claim 3, further comprising:
an N-type doped silicon region, disposed in the first silicon substrate layer, wherein the conductive via structure is electrically connected with the photodiode doped region through the N-type doped silicon region;
the doping concentration in the N-type doped silicon region is higher than that in the photodiode doped region.

5. A method of forming an image sensor, comprising:
providing a semiconductor substrate, wherein the semiconductor substrate comprises a first silicon substrate layer, a substrate oxide layer and a second silicon substrate layer that are stacked;
forming a conductive trench that penetrates through the second silicon substrate layer and the substrate oxide layer;
filling the conductive trench with a conductive material to form a conductive via structure;
forming a floating diffusion in the semiconductor substrate;
forming a transmission gate electrode on a surface of the second silicon substrate layer;
forming a photodiode doped region in the first silicon substrate layer, and the photodiode doped region is electrically connected with the conductive via structure;
the floating diffusion is disposed in the semiconductor substrate on one side of the transmission gate electrode, and the conductive via structure is disposed in the semiconductor substrate on the other side of the transmission gate electrode.

6. The method of forming an image sensor according to claim 5, wherein the first silicon substrate layer has a front and a back, the front of the first silicon substrate layer is in contact with the substrate oxide layer, forming the photodiode doped region in the first silicon substrate layer, comprises:
thinning the first silicon substrate layer from the back;
implanting ions into the first silicon substrate layer from the back of the first silicon substrate layer to form the photodiode doped region.

7. The method of forming an image sensor according to claim 5, wherein the boundary of the photodiode doped region extends to below the floating diffusion.

8. The method of forming an image sensor according to claim 5, wherein the material of the conductive via structure is N-type doped poly-silicon.

9. The method of forming an image sensor according to claim 8, wherein before the step of forming the conductive via structure through filling the conductive trench with a conductive material, the method further comprises:
implanting ions into the first silicon substrate layer exposed from the bottom of the conductive trench to form an N-type doped silicon region located in the first silicon substrate layer;
the bottom of the N-type doped silicon region is connected with the photodiode doped region, and the doping concentration in the N-type doped silicon region is higher than that in the photodiode doped region.

10. The method of forming an image sensor according to claim 9, wherein the doping concentration in the N-type doped silicon region is lower than that in the floating diffusion.
